(19) United States
(12) Patent Application Publication
(10) Pub. No.: US 2026/0042068 A1
(43) Pub. Date: Feb. 12, 2026

(54) FLUORINE RESIN MEMBRANE, FLUORINE RESIN MEMBRANE MEMBER, AND ELECTRONIC DEVICE

(71) Applicant: NITTO DENKO CORPORATION, Osaka (JP)

(72) Inventors: Kodai UEDA, Osaka (JP); Yosuke SUGAYA, Osaka (JP); Tamao FUKUSHIMA, Osaka (JP); Yuichi TAKAMURA, Osaka (JP); Kyoko ISHII, Osaka (JP); Satoru FURUYAMA, Osaka (JP)

(73) Assignee: NITTO DENKO CORPORATION, Osaka (JP)

(21) Appl. No.: 19/124,953

(22) PCT Filed: Nov. 2, 2023
(86) PCT No.: PCT/JP2023/039765

§ 371 Date: Apr. 28, 2025

(30) Foreign Application Priority Data
Nov. 10, 2022 (JP) 2022-180635

(51) Int. Cl. B01D 69/14; B01D 69/02; B01D 71/36; H05K 5/03

(52) U.S. Cl. CPC B01D 69/141; B01D 69/02; B01D 71/36; H05K 5/03; B01D 2325/20; B01D 2325/38

(57) ABSTRACT

A membrane is a fluorine resin membrane having a network structure of a fluorine resin. The network structure includes first string-shaped bodies of the fluorine resin. The first string-shaped bodies have a diameter of 200 nm or more and 750 nm or less when viewed in a direction perpendicular to a principal surface of the fluorine resin membrane. When viewed in the direction, the fluorine resin membrane has, on at least one surface thereof, a region A that has a shape of a rectangle having a size of 8.3 μm×6.2 μm and in which a number of the first string-shaped bodies extending from one long side to another long side of the rectangle is 1 or more and 5 or less. This membrane can be used in a waterproof membrane, and is suitable for enhancing waterproof performance while minimizing a sacrifice of air permeation performance.

### TECHNICAL FIELD

The present invention relates to a fluorine resin membrane, and a fluorine resin membrane member and an electronic device including the same.

### BACKGROUND ART

Electronic devices such as smartphones and smartwatches can have a housing provided with an opening for adjusting the internal pressure of the housing and ensuring air permeability between the inside and the outside of the housing. Normally, a waterproof membrane for preventing entry of foreign matter such as water into the inside of the housing is attached to the opening. Patent Literature 1 discloses a waterproof membrane exhibiting high waterproof performance while having air permeability.

### CITATION LIST

### Patent Literature

Patent Literature 1: JP 2017-184270A

### SUMMARY OF INVENTION

### Technical Problem

In recent years, the waterproof performance required for electronic devices has been increasing. Also, in order to enhance the appeal of products, for example, there is a requirement to support activities that are expected to involve long periods of exposure to water or exposure to high water pressure, such as water sports and diving.

Depending on the level of the requirement, the performance of the waterproof membrane of Patent Literature 1 cannot necessarily be said to be sufficient. Further improvements to the waterproof membrane are desired. However, the waterproof performance and air permeation performance of the waterproof membrane are in a trade-off relationship, and improvements are not easy. It is common knowledge for a person skilled in the art that attempts to enhance waterproof performance result in sacrificing air permeation performance.

The present invention aims to provide a technology suitable for enhancing waterproof performance while minimizing a sacrifice of air permeation performance for a membrane that can be used for a waterproof membrane.

### Solution to Problem

The present invention provides a fluorine resin membrane having a network structure of a fluorine resin, wherein
the network structure includes first string-shaped bodies of the fluorine resin,
the first string-shaped bodies have a diameter of 200 nm or more and 750 nm or less when viewed in a direction perpendicular to a principal surface of the fluorine resin membrane, and
when viewed in the direction, the fluorine resin membrane has, on at least one surface thereof, a region A that has a shape of a rectangle having a size of 8.3 μm×6.2 μm and in which a number of the first string-shaped bodies extending from one long side to another long side of the rectangle is 1 or more and 5 or less.

In another aspect, the present invention provides a fluorine resin membrane having a network structure of a fluorine resin, wherein
the network structure includes first string-shaped bodies and second string-shaped bodies of the fluorine resin,
the first string-shaped bodies and the second string-shaped bodies have a diameter of 200 nm or more and 750 nm or less and a diameter of less than 200 nm, respectively, when viewed in a direction perpendicular to a principal surface of the fluorine resin membrane,
when viewed in the direction, the fluorine resin membrane has, on at least one surface thereof, a region B that has a shape of a rectangle having a size of 8.3 μm×6.2 μm and in which a ring structure composed of the first string-shaped body is observed, and
a number of the second string-shaped bodies observed inside the largest ring structure existing in the region B when viewed in the direction is 6 or more.

In still another aspect, the present invention provides a fluorine resin membrane having a network structure of a fluorine resin, wherein
a Gurley air permeability per 1 μm thickness of the fluorine resin membrane is 5 seconds/100 mL/μm or less, and
a limit water entry pressure of the fluorine resin membrane is 1.6 MPa or more.

In still another aspect, the present invention provides a fluorine resin membrane having a network structure of a fluorine resin, wherein
a Gurley air permeability per 1 μm thickness of the fluorine resin membrane is 5 seconds/100 mL/μm or less, and
the fluorine resin membrane has retention waterproofness that can withstand a water pressure retention test in which the fluorine resin membrane is exposed to a water pressure of 1.0 MPa for 30 minutes when a circular water pressure application surface having a diameter of 1 mm is set.

In still another aspect, the present invention provides a fluorine resin membrane member including:
the fluorine resin membrane of the present invention; and
a support layer and/or an adhesive layer.

In still another aspect, the present invention provides an electronic device including:
a housing having an opening; and
a waterproof membrane attached to the housing so as to cover the opening, wherein
the waterproof membrane includes the fluorine resin membrane of the present invention.

### Advantageous Effects of Invention

The fluorine resin membrane of the present invention is a membrane that can be used in a waterproof membrane, and is suitable for enhancing waterproof performance while minimizing a sacrifice of air permeation performance.

### BRIEF DESCRIPTION OF THE DRAWINGS

FIG. 1 shows a plan view schematically showing an example of a fluorine resin membrane of the present invention and a partially enlarged view of a part thereof.

FIG. 2 is a plan view schematically showing an example of a region A in the fluorine resin membrane of the present invention.

FIG. 3A is a schematic diagram for describing a method for calculating the number of first string-shaped bodies.

FIG. 3B is a schematic diagram for describing a method for calculating the number of first string-shaped bodies.

FIG. 3C is a schematic diagram for describing a method for calculating the number of first string-shaped bodies.

FIG. 3D is a schematic diagram for describing a method for calculating the number of first string-shaped bodies.

FIG. 4A is a schematic diagram for describing a method for calculating the number of second string-shaped bodies observed inside a ring structure composed of a first string-shaped body.

FIG. 4B is a schematic diagram for describing a method for calculating the number of second string-shaped bodies observed inside a ring structure composed of a first string-shaped body.

FIG. 4C is a schematic diagram for describing a method for calculating the number of second string-shaped bodies observed inside a ring structure composed of a first string-shaped body.

FIG. 4D is a schematic diagram for describing a method for calculating the number of second string-shaped bodies observed inside a ring structure composed of a first string-shaped body.

FIG. 4E is a schematic diagram for describing a method for calculating the number of second string-shaped bodies observed inside a ring structure composed of a first string-shaped body.

FIG. 4F is a schematic diagram for describing a method for calculating the number of second string-shaped bodies observed inside a ring structure composed of a first string-shaped body.

FIG. 4G is a schematic diagram for describing a method for calculating the number of second string-shaped bodies observed inside a ring structure composed of a first string-shaped body.

FIG. 4H is a schematic diagram for describing a method for calculating the number of second string-shaped bodies observed inside a ring structure composed of a first string-shaped body.

FIG. 5 is a plan view schematically showing an example of the fluorine resin membrane of the present invention.

FIG. 6 is a cross-sectional view schematically showing an example of a fluorine resin membrane member of the present invention.

FIG. 7A is a cross-sectional view schematically showing an example of the fluorine resin membrane member of the present invention.

FIG. 7B is a cross-sectional view schematically showing an example of the fluorine resin membrane member of the present invention.

FIG. 8A is a cross-sectional view schematically showing an example of an electronic device of the present invention.

FIG. 8B is a cross-sectional view schematically showing an example of the electronic device of the present invention.

FIG. 9 is a magnified observation image of the surface of Sample 2 produced in the examples.

FIG. 10 is a magnified observation image of the surface of Sample 10 produced in the examples.

### DESCRIPTION OF EMBODIMENTS

A membrane according to a first aspect of the present invention is a fluorine resin membrane having a network structure of a fluorine resin, wherein
the network structure includes first string-shaped bodies of the fluorine resin,
the first string-shaped bodies have a diameter of 200 nm or more and 750 nm or less when viewed in a direction perpendicular to a principal surface of the fluorine resin membrane, and
when viewed in the direction, the fluorine resin membrane has, on at least one surface thereof, a region A that has a shape of a rectangle having a size of 8.3 μm×6.2 μm and in which a number of the first string-shaped bodies extending from one long side to another long side of the rectangle is 1 or more and 5 or less.

In a second aspect of the present invention, for example, in the fluorine resin membrane according to the first aspect, the network structure further includes second string-shaped bodies of the fluorine resin, and the second string-shaped bodies have a diameter of less than 200 nm when viewed in a direction perpendicular to the principal surface of the fluorine resin membrane.

In a third aspect of the present invention, for example, in the fluorine resin membrane according to the first or second aspect, a ring structure composed of the first string-shaped body is observed in the region A.

In a fourth aspect of the present invention, for example, in the fluorine resin membrane according to the third aspect, the network structure further includes second string-shaped bodies of the fluorine resin, the second string-shaped bodies have a diameter of less than 200 nm when viewed in a direction perpendicular to the principal surface of the fluorine resin membrane, and a number of the second string-shaped bodies observed inside the largest ring structure existing in the region A when viewed in the direction is 6 or more.

In a fifth aspect of the present invention, for example, in the fluorine resin membrane according to the fourth aspect, the number of the second string-shaped bodies is 17 or less.

In a sixth aspect of the present invention, for example, in the fluorine resin membrane according to any one of the first to fifth aspects, a proportion of an area of the string-shaped bodies of the fluorine resin in the region A is 60% or less.

In a seventh aspect of the present invention, for example, in the fluorine resin membrane according to any one of the first to sixth aspects, a Gurley air permeability per 1 μm thickness of the fluorine resin membrane is 5 seconds/100 mL/μm or less.

In an eighth aspect of the present invention, for example, a limit water entry pressure of the fluorine resin membrane according to any one of the first to seventh aspects is 1.6 MPa or more.

In a ninth aspect of the present invention, for example, the fluorine resin membrane according to any one of the first to eighth aspects has retention waterproofness that can withstand a water pressure retention test in which the fluorine resin membrane is exposed to a water pressure of 1.0 MPa for 30 minutes when a circular water pressure application surface having a diameter of 1 mm is set.

In a tenth aspect of the present invention, for example, in the fluorine resin membrane according to any one of the first to ninth aspects, the fluorine resin is polytetrafluoroethylene.

A membrane according to an eleventh aspect of the present invention is a fluorine resin membrane having a network structure of a fluorine resin, wherein
the network structure includes first string-shaped bodies and second string-shaped bodies of the fluorine resin,
the first string-shaped bodies and the second string-shaped bodies have a diameter of 200 nm or more and 750 nm or less and a diameter of less than 200 nm, respectively, when viewed in a direction perpendicular to a principal surface of the fluorine resin membrane,
when viewed in the direction, the fluorine resin membrane has, on at least one surface thereof, a region B that has a shape of a rectangle having a size of 8.3 μm×6.2 μm and in which a ring structure composed of the first string-shaped body is observed, and
a number of the second string-shaped bodies observed inside the largest ring structure existing in the region B when viewed in the direction is 6 or more.

A membrane according to a twelfth aspect of the present invention is a fluorine resin membrane having a network structure of a fluorine resin, wherein
a Gurley air permeability per 1 μm thickness of the fluorine resin membrane is 5 seconds/100 mL/μm or less, and
a limit water entry pressure of the fluorine resin membrane is 1.6 MPa or more.

A membrane according to a thirteenth aspect of the present invention is a fluorine resin membrane having a network structure of a fluorine resin, wherein
a Gurley air permeability per 1 μm thickness of the fluorine resin membrane is 5 seconds/100 mL/μm or less, and
the fluorine resin membrane has retention waterproofness that can withstand a water pressure retention test in which the fluorine resin membrane is exposed to a water pressure of 1.0 MPa for 30 minutes when a circular water pressure application surface having a diameter of 1 mm is set.

A fluorine resin membrane member according to a fourteenth aspect of the present invention includes:
the fluorine resin membrane according to any one of the first to thirteenth aspects; and
a support layer and/or an adhesive layer.

An electronic device according to a fifteenth aspect of the present invention includes:
a housing having an opening; and
a waterproof membrane attached to the housing so as to cover the opening, wherein
the waterproof membrane includes the fluorine resin membrane according to any one of the first to thirteenth aspects.

Hereinafter, embodiments of the present invention will be described with reference to the drawings. The present invention is not limited to the following embodiments.

### [Fluorine Resin Membrane]

### First Embodiment

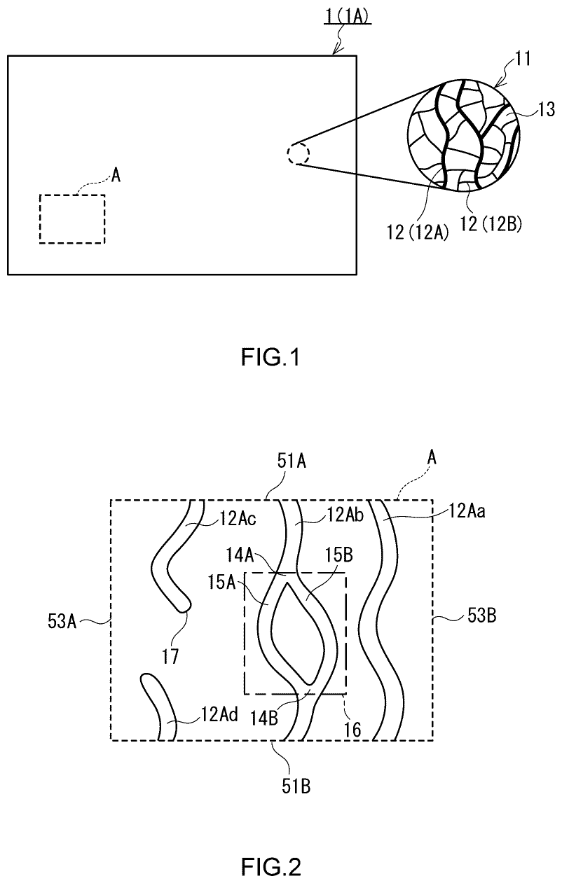

An example of a fluorine resin membrane of the present embodiment is shown in FIG. 1. FIG. 1 also shows a partially enlarged view of the surface of a fluorine resin membrane 1 (1A). The fluorine resin membrane 1A has a network structure 11 of a fluorine resin. The network structure 11 includes string-shaped bodies 12 of the fluorine resin. The network structure 11 has voids 13 between the string-shaped bodies 12, and air permeability in the thickness direction of the fluorine resin membrane 1 is mainly ensured by the voids 13. The network structure 11 in FIG. 1 includes, as the string-shaped bodies 12, first string-shaped bodies 12A having a diameter of 200 nm or more and 750 nm or less when viewed in a direction perpendicular to a principal surface of the fluorine resin membrane 1 (hereinafter referred to as perpendicular direction) and second string-shaped bodies 12B having a diameter of less than 200 nm when viewed in the perpendicular direction.

In the present description, the string-shaped bodies 12 are classified according to the diameters thereof. The string-shaped bodies 12 having a diameter of 200 nm or more and 750 nm or less when viewed in the perpendicular direction are the first string-shaped bodies 12A. The string-shaped bodies 12 having a diameter of less than 200 nm when viewed in the perpendicular direction are the second string-shaped bodies 12B. The string-shaped bodies 12 having a diameter exceeding 750 nm when viewed in the perpendicular direction are third string-shaped bodies. However, the diameters of the string-shaped bodies 12 can vary in a length direction thereof. If there is a point where the diameter changes beyond a boundary value of 200 nm and/or 750 nm when one string-shaped body 12 is traced in the length direction thereof, it is determined, for each section before and after the change in the string-shaped body 12, whether the section corresponds to a first, second, or third string-shaped body, based on the diameter of the section. For example, if a string-shaped body 12 has a first section having a diameter of 200 nm or more and 750 nm or less and a second section having a diameter of less than 200 nm, the first section is a first string-shaped body 12A, and the second section is a second string-shaped body 12B. The lower limit of the diameter of each second string-shaped body 12B is, for example, 20 nm or more. The upper limit of the diameter of each third string-shaped body is, for example, 4500 nm or less.

The diameter of each string-shaped body 12 can be obtained from a magnified observation image of the fluorine resin membrane 1 in which the string-shaped body 12 can be confirmed in the perpendicular direction. Image analysis using image analysis software such as ImageJ may also be used. When the diameter of the string-shaped body 12 is to be evaluated, it is preferable to maximize the gradation between the darkest point and the brightest point in the magnified observation image, in the range of gradation used in the analysis, for a brightness histogram. The magnified observation image is, for example, an observation image obtained using a scanning electron microscope (SEM). The magnification is, for example, 5000 to 25000 times, preferably 10000 to 20000 times, and more preferably 15000 times. The acceleration voltage is usually set to 1 kV. Once the acceleration voltage is determined, the depth of the magnified observation image (the range of depth from the membrane surface that can be observed in the image) is determined. The magnified observation image obtained using this method can also be used to determine a number A and a number B described later.

The fluorine resin membrane 1A has a region A having the following characteristics (1) and (2) when viewed in the perpendicular direction.
(1) It has a shape of a rectangle having a size of 8.3 μm×6.2 μm.
(2) The number of first string-shaped bodies 12A observed and extending from one long side to another long side of the rectangle (hereinafter referred to as number A) is 1 or more and 5 or less.

The number A may be 2 or more, may be 4 or less, or may be 1 or more and 3 or less. The fact that the number A is in the above range can contribute to enhancing waterproof performance while minimizing a sacrifice of air permeation performance for the fluorine resin membrane 1. An example of the region A is shown in FIG. 2. FIG. 2 shows only the first string-shaped bodies 12A out of the string-shaped bodies 12 observed in the region A. The number A in the region A in FIG. 2 is 2 corresponding to two first string-shaped bodies 12Aa and 12Ab. A first string-shaped body 12Ac extends from a long side 51A, and then, for example, the first string-shaped body 12Ac disappears at its end 17 or the diameter thereof deviates from the range of 200 nm or more and 750 nm or less, and thus the first string-shaped body 12Ac does not extend to a long side 51B. Therefore, the first string-shaped body 12Ac is excluded from the calculation of the number A. In addition, a first string-shaped body 12Ad does not extend from the long side 51A, and is similarly excluded from the calculation of the number A.

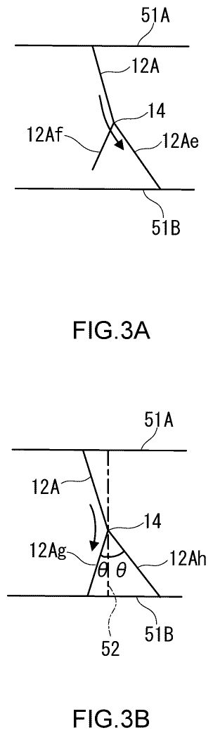

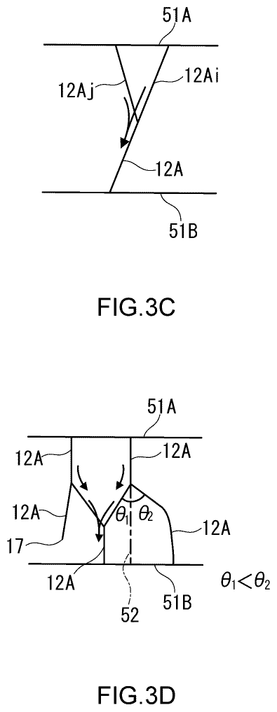

The method for calculating the number A will be described in more detail. In principle, each first string-shaped body 12A connected to the one long side 51A of the region A is traced in the length direction thereof, and the number of first string-shaped bodies 12A reaching the other long side 51B is calculated. However, the first string-shaped bodies 12A can have branches. The case where the first string-shaped body 12A has a branch will be described with reference to FIG. 3A to FIG. 3D. In FIG. 3A to FIG. 3D, the first string-shaped body 12A is represented by a center line in a width direction thereof. Of two or more first string-shaped bodies 12A that diverge at a branching point 14, a first string-shaped body 12Af that does not reach the other long side 51B is excluded from the calculation of the number A (see FIG. 3A). In the example in FIG. 3A, one first string-shaped body 12Ae reaches the other long side 51B. Therefore, the number A calculated in the example in FIG. 3A is 1. Next, if, of the two or more first string-shaped bodies 12A that diverge at the branching point 14, a plurality of first string-shaped bodies 12Ag and 12Ah reach the long side 51B, only the first string-shaped body 12Ag having a smallest angle θ with a straight line 52 that passes through the branching point 14 and is perpendicular to the long sides 51A and 51B is traced (see FIG. 3B). In other words, the first string-shaped body 12Ah whose angle θ is not the smallest is excluded from the calculation of the number A (see FIG. 3B). The number A calculated in the example in FIG. 3B is 1. If a plurality of first string-shaped bodies 12A whose angles θ are the smallest and the same are observed, 1 before branching is calculated as the number A. This rule is consistent with a rule for merging, which is illustrated in FIG. 3C. Next, if two or more first string-shaped bodies 12Ai and 12Aj extending from the long side 51A merge to form one first string-shaped body 12A and reach the long side 51B, 1 that is the number of first string-shaped bodies 12A reaching the long side 51B is calculated (see FIG. 3C). Another example is shown in FIG. 3D. If the above rules are followed, the number A calculated in the example in FIG. 3D is 1.

In the region A, the first string-shaped bodies 12A extending from one short side 53A to another short side 53B of the rectangle may not be observed.

The direction in which the long sides 51A and 51B of the region A extend and the direction in which the short sides 53A and 53B of the region A extend may be an MD direction and a TD direction of the fluorine resin membrane 1, respectively. The MD direction and the TD direction of the fluorine resin membrane 1 are respectively, for example, the directions of longitudinal stretching and transverse stretching when the fluorine resin membrane 1 is produced.

In the region A, a ring structure composed of a first string-shaped body 12A may be observed. In the region A illustrated in FIG. 2, a ring structure 16 composed of the first string-shaped body 12Ab is observed. The observed ring structure 16 is composed of first string-shaped bodies 15A and 15B that diverge at a branching point 14A and merge at a branching point 14B when the first string-shaped body 12Ab is traced in the direction from the long side 51A to the long side 51B. The fluorine resin membrane 1 in which the ring structure 16 is observed in the region A is particularly suitable for enhancing waterproof performance while minimizing a sacrifice of air permeation performance. In the ring structure 16, there may be a branch of a first string-shaped body 12A, a second string-shaped body 12B, or a third string-shaped body extending outward or inward from the ring structure 16. However, in the ring structure 16 itself, a section composed of a second string-shaped body 12B or a third string-shaped body does not exist. The ring structure 16 may typically have a bending portion at a branching point of the first string-shaped body 12A. The entire circumference of the ring structure 16 needs to be observed within the region A. A plurality of ring structures 16 may be observed in the region A, and in this case, adjacent ring structures 16 may share a part of a circumference. In the inside of a ring structure 16, another ring structure 16 having a smaller area may be observed.

The area of the ring structure 16 when viewed in the perpendicular direction is, for example, 0.3 to 20 μm². The lower limit of the area may be 0.5 μm² or more, 1 μm² or more, 1.5 μm² or more, 2 μm or more, or even 2.5 μm² or more. The upper limit of the area may be 15 μm² or less, 13 μm² or less, 10 μm² or less, 8 μm² or less, or even 5 μm² or less. The area of the ring structure 16 can be specified as the area of a region surrounded by the inner circumference of the ring structure 16. Image analysis of a magnified observation image can be used to specify the area.

As shown in FIG. 1, the network structure 11 may include second string-shaped bodies 12B of the fluorine resin. In this case, the number of second string-shaped bodies 12B observed inside the largest ring structure 16 existing in the region A when viewed in the perpendicular direction (hereinafter referred to as number B) may be 6 or more, 7 or more, 8 or more, 9 or more, or even 10 or more. The upper limit of the number B is, for example, 30 or less, and may be 27 or less, 25 or less, 24 or less, 23 or less, 22 or less, 21 or less, 20 or less, 19 or less, 18 or less, 17 or less, 16 or less, or even 15 or less. The number B may be 6 or more and 20 or less, 8 or more and 17 or less, or even 10 or more and 15 or less. The fluorine resin membrane 1 in which the number B is in the above range is particularly suitable for enhancing waterproof performance while minimizing a sacrifice of air permeation performance.

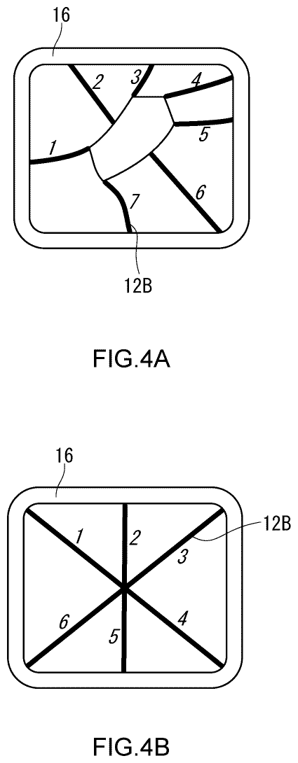

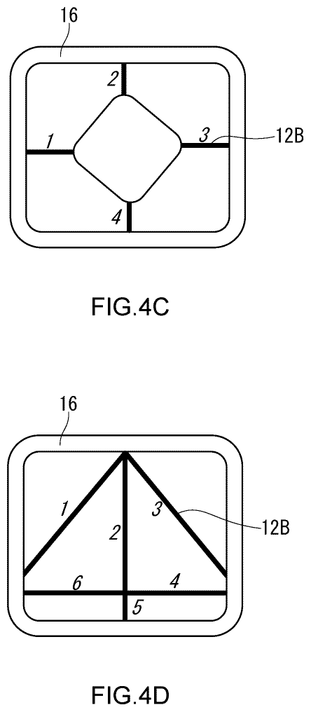

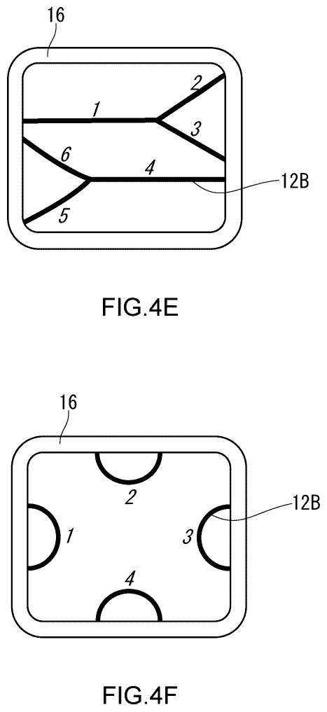

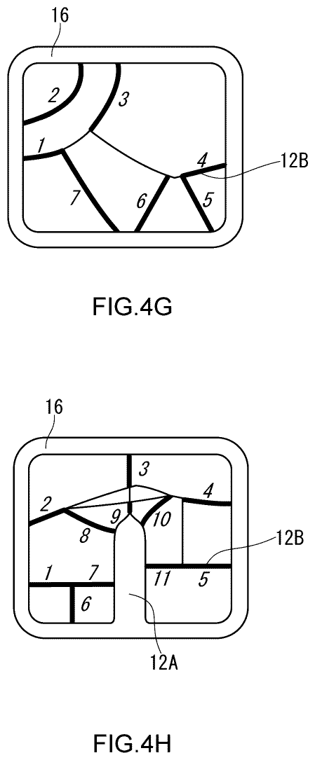

The method for calculating the number B of second string-shaped bodies 12B observed inside the ring structure 16 will be described. In principle, for each second string-shaped body 12B observed as extending from the circumference of the ring structure 16 to the inside of the ring structure 16 when viewed in the perpendicular direction, a section to a point of merging, intersecting, or branching with another string-shaped body 12 is counted as 1, and the total of such counts is regarded as the number B. The other string-shaped body 12 may be a first string-shaped body 12A, a second string-shaped body 12B, or a third string-shaped body. For example, the numbers B in examples shown in FIG. 4A to FIG. 4G are 7, 6, 4, 6, 6, 4, and 7, respectively. In FIG. 4A to FIG. 4G and FIG. 4H, only the ring structure 16 and the second string-shaped body 12B are shown. In addition, in FIG. 4A to FIG. 4G and FIG. 4H, the sections from the circumference of the ring structure 16 to the above points in the second string-shaped body 12B are shown by a thick line. The number of sections shown by the thick line corresponds to the number B. However, if a first string-shaped body 12A diverging from the circumference of the ring structure 16 and extending in the inside of the ring structure 16 is observed, a second string-shaped body 12B observed as extending in the inside of the ring structure 16 from the first string-shaped body 12A extending in the inside is also taken into account in the calculation of the number B. For example, the number B in the example in FIG. 4H is 11.

In the region A, a third string-shaped body of the fluorine resin having a diameter exceeding 750 nm when viewed in the perpendicular direction and extending from one long side to another long side of the region A may not be observed. In the region A, a third string-shaped body of the fluorine resin having a diameter exceeding 750 nm when viewed in the perpendicular direction and having a length exceeding 1000 nm does not may not be observed. In addition, the network structure 11 may include no third string-shaped body of the fluorine resin having a diameter exceeding 750 nm when viewed in the perpendicular direction and having a length exceeding 1000 nm. These aspects are particularly suitable for enhancing waterproof performance while minimizing a sacrifice of air permeation performance. The length of the string-shaped body can be obtained by tracing the center in the width direction of the string-shaped body, in the length direction of the string-shaped body, when the string-shaped body is viewed in the perpendicular direction.

The proportion of the area of the string-shaped bodies 12 of the fluorine resin in the region A is, for example, 60% or less, and may be 59% or less, 58% or less, 57% or less, 56% or less, 55% or less, 54% or less, 53% or less, 52% or less, 51% or less, 50% or less, or even 49% or less. The lower limit of the proportion of the area is, for example, 40% or more. The fluorine resin membrane 1 in which the proportion of the area is in the above range is particularly suitable for enhancing waterproof performance while minimizing a sacrifice of air permeation performance. The proportion of the area of the string-shaped bodies 12 of the fluorine resin in the region A can be evaluated by performing image processing, including binarization, on a magnified observation image. Binarization can be performed such that the string-shaped bodies 12 and the voids 13 can be distinguished from each other.

In the region A, fibrils formed by fiberization of the fluorine resin may not be observed. In addition, the network structure 11 may not include the above fibrils. The fibrils and the string-shaped bodies 12 differ at least in that the fibrils can have unique crystals that are formed by fiberization. As an example, a general porous PTFE membrane having a so-called node/fibril structure shows an endothermic peak specific to the above crystals and located at 360 to 385° C. in differential scanning calorimetry (DSC) (see JP 2021-54892 A). In other words, the fluorine resin membrane 1 in which the fluorine resin is PTFE may not have an endothermic peak located at 360 to 385° C. in a DSC chart. For a specific DSC measurement method, the above publication can be referred to. A general porous PTFE membrane is formed by extruding a mixture of unsintered PTFE molding powder and a liquid lubricant into a sheet shape, removing the liquid lubricant from the obtained unsintered PTFE sheet, and stretching this PTFE sheet.

The fluorine resin membrane 1 has the region A on at least one surface thereof. The fluorine resin membrane 1 may have the region A on both surfaces thereof.

The thickness of the fluorine resin membrane 1 is, for example, 5 to 100 μm. The upper limit of the thickness may be 90 μm or less, 80 μm or less, 70 μm or less, 60 μm or less, 50 μm or less, 45 μm or less, 40 μm or less, 35 μm or less, 30 μm or less, 25 μm or less, or even 20 μm or less. The lower limit of the thickness may be 7 μm or more, 10 μm or more, 12 μm or more, 13 μm or more, 15 μm or more, 17 μm or more, 20 μm or more, 22 μm or more, 25 μm or more, 27 μm or more, or even 30 μm or more. The thickness may be 25 μm or more and 40 μm or less, 30 μm or more and 35 μm or less, 31 μm or more and 34 μm or less, 32 μm or more and 34 μm or less, or even 33 μm or more and 34 μm or less.

For the fluorine resin membrane 1, the number A may be 1 or more and 3 or less, the number B may be 10 or more and 15 or less, and the thickness may be 33 μm or more and 34 μm or less.

The Gurley air permeability in the thickness direction of the fluorine resin membrane 1 is, for example, 150 seconds/100 mL or less, and may be 120 seconds/100 mL or less, 100 seconds/100 mL or less, 95 seconds/100 mL or less, 90 seconds/100 mL or less, 85 seconds/100 mL or less, 80 seconds/100 mL or less, 75 seconds/100 mL or less, 70 seconds/100 mL or less, 65 seconds/100 mL or less, 60 seconds/100 mL or less, 55 seconds/100 mL or less, 50 seconds/100 mL or less, 45 seconds/100 mL or less, or even 40 seconds/100 mL or less. The lower limit of the Gurley air permeability is, for example, 10 seconds/100 mL or more, and may be 20 seconds/100 mL or more, 30 seconds/100 mL or more, 35 seconds/100 mL or more, 40 seconds/100 mL or more, 45 seconds/100 mL or more, 50 seconds/100 mL or more, 55 seconds/100 mL or more, 60 seconds/100 mL or more, 65 seconds/100 mL or more, 70 seconds/100 mL or more, 75 seconds/100 mL or more, or even 80 seconds/100 mL or more. In the present description, the “Gurley air permeability” means an air permeability as expressed by degree of air permeation measured in accordance with Method B of air permeability measurement (Gurley method) prescribed in Japanese Industrial Standards (hereinafter, referred to as “JIS”) L 1096: 2010.

Even in the case where the fluorine resin membrane 1 has a size that fails to satisfy the size (approximately 50 mm×50 mm) of a specimen used in the Gurley method, it is possible to evaluate the Gurley air permeability by using a measuring jig. An example of the measuring jig is a polycarbonate disk that has a thickness of 2 mm and a diameter of 47 mm and that is provided, at a center thereof, with a through hole (having a circular cross section with a diameter of 1 mm or 2 mm). The measurement of the Gurley air permeability using this measuring jig can be carried out as follows.

The fluorine resin membrane 1 to be evaluated is fixed on one surface of the measuring jig in such a manner as to cover an opening of the through hole of the measuring jig. The fixation is carried out in such a manner that when the Gurley air permeability is being measured, air permeates only through the opening and an effective test region (a region that overlaps with the opening when viewed in the direction perpendicular to the principal surface of the fixed fluorine resin membrane 1) of the fluorine resin membrane 1 to be evaluated and a fixed portion does not inhibit the permeation of the air through the effective test region of the fluorine resin membrane 1. To fix the fluorine resin membrane 1, a double-coated adhesive tape provided with an air passing port that has a shape identical to that of the opening and that is punched at a central part of the adhesive tape can be used. The double-coated adhesive tape may be disposed between the measuring jig and the fluorine resin membrane 1 in such a manner that a circumference of the air passing port is aligned with a circumference of the opening. Next, the measuring jig with the fluorine resin membrane 1 fixed thereon is set on a Gurley air permeability tester in such a manner that a surface on which the fluorine resin membrane 1 is fixed is on a downstream side of an airstream at the time of the measurement, and a time t1 that 100 mL of air spends permeating the fluorine resin membrane 1 is measured. Next, the time t1 measured is converted to a value t per 642 [mm²], which is an effective test area prescribed in Method B of air permeability measurement (Gurley method) in JIS L 1096: 2010, by an equation t={(t1)×an area [mm²] of the effective test region of the fluorine resin membrane 1)/642 [mm²]}, so that the converted value t thus obtained can be defined as the Gurley air permeability of the fluorine resin membrane 1. In the case where the above-mentioned disk is used as the measuring jig, the area of the effective test region of the fluorine resin membrane 1 is an area of the cross section of the through hole. It has been confirmed that the Gurley air permeability measured, without the measuring jig, on the fluorine resin membrane 1 that satisfies the above-mentioned size of the specimen is sufficiently equal to the Gurley air permeability measured on a piece of the fluorine resin membrane 1 with the measuring jig. That is, it has been confirmed that use of the measuring jig has substantially no impact on the Gurley air permeability measurements.

For the fluorine resin membrane 1, a Gurley air permeability per 1 μm thickness (unit: seconds/100 mL/μm) is, for example, 5 or less, and may be 4.5 or less, 4 or less, 3.5 or less, 3.3 or less, 3.1 or less, 3 or less, 2.9 or less, 2.8 or less, 2.7 or less, 2.6 or less, 2.5 or less, or even 2.4 or less. The lower limit of the Gurley air permeability per 1 μm thickness is, for example, 2 or more.

For the fluorine resin membrane 1, a limit water entry pressure, which is one index of waterproof performance, is, for example, 1.5 MPa or more, and may be 1.6 MPa or more, 1.7 MPa or more, 1.8 MPa or more, 1.9 MPa or more, or even 2 MPa or more. The upper limit of the limit water entry pressure is, for example, 4 MPa or less. The limit water entry pressure can be measured in accordance with Method B (high hydraulic pressure method) of water penetration test prescribed in JIS L 1092: 2009, using the measuring jig, as follows. An example of the measuring jig is a stainless-steel disk that has a diameter of 47 mm and that is provided, at a center thereof, with a through hole (having a circular cross section) with a diameter of 1 mm. This disk has a thickness that prevents the disk from being deformed by a hydraulic pressure to be applied at the time of measuring the limit water entry pressure. The measurement of the limit water entry pressure using the measuring jig can be carried out as follows.

The fluorine resin membrane 1 to be evaluated is fixed on one surface of the measuring jig in such a manner as to cover an opening of the through hole of the measuring jig. The fixation is carried out in such a manner that no water leaks from a fixed portion of the membrane when the limit water entry pressure is being measured. To fix the fluorine resin membrane 1, a double-coated adhesive tape provided with a water passing port that is punched at a central part of the adhesive tape can be used. The double-coated adhesive tape may be disposed between the measuring jig and the fluorine resin membrane 1 in such a manner that the portion of the double-coated adhesive tape other than the water passing port does not overlap the inside of the opening of the measuring jig when viewed in the perpendicular direction. Next, the measuring jig with the fluorine resin membrane 1 fixed thereon is set on a test apparatus in such a manner that a surface on which the fluorine resin membrane 1 is fixed is a surface on which a hydraulic pressure is applied at the time of measurement. Then, the limit water entry pressure is measured in accordance with Method B (high hydraulic pressure method) of water penetration test prescribed in JIS L 1092: 2009. It should be noted that the water entry pressure is measured based on the hydraulic pressure at the time when water comes out from one spot of a surface of the fluorine resin membrane 1. The water entry pressure measured can be defined as the limit water entry pressure of the fluorine resin membrane 1. As the test apparatus, an apparatus that has a structure equivalent to that of a water penetration test apparatus illustrated in JIS L 1092: 2009 and that has a specimen mounting structure allowing the above-mentioned measuring jig to be set thereon can be used.

For the fluorine resin membrane 1, there is also retention waterproofness as another index of waterproof performance. Having retention waterproofness for a predetermined water pressure and water pressure application time can be evaluated by ensuring that the fluorine resin membrane 1 does not burst or leak water even when a predetermined water pressure is continuously applied to the fluorine resin membrane 1 for a predetermined time. The water pressure retention test can be conducted using the same measuring jig and water penetration test apparatus illustrated in JIS L 1092: 2009 as for the limit water entry pressure. A surface to which the water pressure is applied, or a water pressure application surface, is the surface of the fluorine resin membrane 1 that is fixed to the measuring jig. The diameter of the through hole of the measuring jig is 1 mm or 0.2 mm. The diameter of the through hole being X mm means that a circular water pressure application surface having a diameter of X mm is set for the fluorine resin membrane 1 in the water pressure retention test. The studies made by the present inventors reveal that there is a possibility that a particularly well-balanced membrane structure is required in order to ensure retention waterproofness. For example, even if membranes have the same limit water entry pressure, the retention waterproofness of these membranes can differ greatly. The number A and/or the number B can contribute to achieving a well-balanced membrane structure.

The fluorine resin membrane 1 may have retention waterproofness that can withstand a water pressure retention test in which the fluorine resin membrane 1 is exposed to a water pressure of 1.0 MPa for 30 minutes when a circular water pressure application surface having a diameter of 1 mm is set. The fluorine resin membrane 1 may have retention waterproofness that can withstand a water pressure retention test in which the fluorine resin membrane 1 is exposed to a water pressure of 1.25 MPa for 30 minutes when a circular water pressure application surface having a diameter of 1 mm is set. The fluorine resin membrane 1 may have retention waterproofness that can withstand a water pressure retention test in which the fluorine resin membrane 1 is exposed to a water pressure of 1.5 MPa for 30 minutes when a circular water pressure application surface having a diameter of 0.2 mm is set.

The fluorine resin membrane 1 can have a Gurley air permeability per 1 μm thickness in the above-described range, including the preferred range, and a limit water entry pressure and/or retention waterproofness in the above-described range, including the preferred range, at the same time.

The mass per unit area of the fluorine resin membrane 1 is, for example, 5 to 40 g/m². The upper limit of the mass per unit area may be 35 g/m² or less, 32 g/m² or less, 30 g/m² or less, 27 g/m² or less, 25 g/m² or less, 22 g/m² or less, 20 g/m² or less, or even 18 g/m² or less. The lower limit of the surface density may be 8 g/m² or more, 10 g/m² or more, 13 g/m² or more, 15 g/m² or more, 18 g/m² or more, 20 g/m² or more, 23 g/m² or more, 25 g/m² or more, 28 g/m² or more, or even 30 g/m² or more. The mass per unit area can be calculated by dividing the mass of the fluorine resin membrane 1 by the area (area of the principal surface) of the fluorine resin membrane 1.

The fluorine resin membrane 1 may be a single layer membrane, or a laminate composed of two or more membranes.

The fluorine resin membrane 1 may be a colored membrane. The fluorine resin membrane 1 may be colored gray or black, for example. The gray or black fluorine resin membrane 1 can be formed by, for example, mixing a gray or black colorant with the material which the membrane is formed of. The black colorant is carbon black, for example. A color in the range of 1 to 4 and a color in the range of 5 to 8 as expressed by “achromatic color lightness NV” prescribed in JIS Z8721: 1993 can be determined respectively as “black” and “gray”.

The fluorine resin membrane 1 may be subjected to a water-repellent treatment, an oil-repellent treatment, or a liquid-repellent treatment. The liquid-repellent treatment is a treatment that provides the fluorine resin membrane 1 with both water repellent and oil repellent properties.

The fluorine resin membrane 1 has, for example, a shape of a circle, an ellipse, a polygon such as a square and a rectangle, or a stripe, when viewed in the perpendicular direction. The corners of the polygon may be rounded. However, the shape of the fluorine resin membrane 1 is not limited to the above examples.

The fluorine resin membrane 1 can be distributed commercially in a shape in which the fluorine resin membrane 1 is to be actually used, and also as a roll of a strip-shaped membrane. In the case of distributing commercially the fluorine resin membrane 1 in the shape in which the fluorine resin membrane 1 is to be actually used, a sheet including a base film and one or two pieces of the fluorine resin membrane 1 in that shape placed thereon may be distributed commercially. The surface of the base film on which the fluorine resin membrane(s) 1 is placed may have tackiness. The tackiness of the surface on which the fluorine resin membrane(s) 1 is placed may be weak tackiness or slight tackiness. The fluorine resin membrane 1 as a roll can be used, for example, after being punched out into a predetermined shape.

The fluorine resin that can be contained in the fluorine resin membrane 1, more specifically, the fluorine resin that can form the network structure 11, is, for example, polytetrafluoroethylene (hereinafter referred to as PTFE), an ethylene-tetrafluoroethylene copolymer (ETFE), a perfluoroalkoxy alkane (PFA), or a tetrafluoroethylene-hexafluoropropylene copolymer (FEP). The fluorine resin is preferably PTFE. The fluorine resin membrane 1 containing PTFE has a particularly good balance of mass and strength and has particularly excellent heat resistance. In addition, the fluorine resin membrane 1 containing PTFE is particularly suitable for carrying out a heat treatment, such as a solder reflow process, in a state where the fluorine resin membrane 1 is attached to the housing of an electronic device.

The fluorine resin membrane 1 may or may not necessarily contain another material other than the fluorine resin. The fluorine resin membrane 1 may or may not necessarily contain another material other than the fluorine resin that forms the network structure 11. In the case where the fluorine resin membrane 1 does not contain another material, the fluorine resin membrane 1 can have high insulation properties derived from the fluorine resin. In other words, the fluorine resin membrane 1 may be an insulating membrane. The fact that the fluorine resin membrane 1 is an insulating membrane can be confirmed, for example, by having a surface resistivity of 1×10¹⁴Ω/□ or more.

### Second Embodiment

The fluorine resin membrane 1 of the present invention can also be expressed by the number B of second string-shaped bodies 12B observed inside the ring structure 16. A fluorine resin membrane 1 (1B) in which the number B is 6 or more is suitable for enhancing waterproof performance while minimizing a sacrifice of air permeation performance.

In this aspect, a fluorine resin membrane of a second embodiment is a fluorine resin membrane having a network structure of a fluorine resin, wherein
the network structure includes first string-shaped bodies and second string-shaped bodies of the fluorine resin,
the first string-shaped bodies and the second string-shaped bodies have a diameter of 200 nm or more and 750 nm or less and a diameter of less than 200 nm, respectively, when viewed in the perpendicular direction,
when viewed in the perpendicular direction, the fluorine resin membrane has, on at least one surface thereof, a region B that has a shape of a rectangle having a size of 8.3 μm×6.2 μm and in which a ring structure composed of a first string-shaped body is observed, and
a number of second string-shaped bodies observed inside the largest ring structure existing in the region B when viewed in the perpendicular direction is 6 or more.

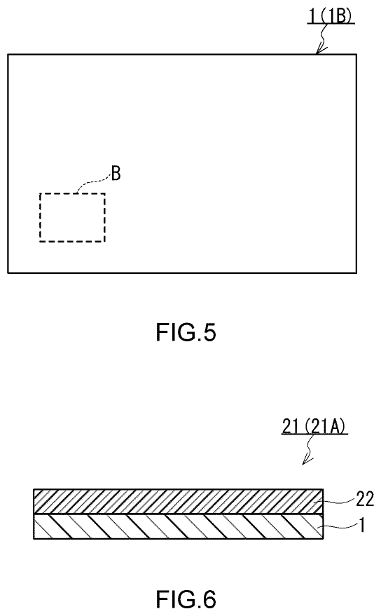

An example of the fluorine resin membrane 1B of the second embodiment is shown in FIG. 5. The fluorine resin membrane 1B of the second embodiment can have the number B and/or the number A, including the preferred range, described above in the description of the first embodiment, for the first string-shaped bodies 12A and the second string-shaped bodies 12B. In addition, the fluorine resin membrane 1B can have the characteristics and/or the membrane configuration of the fluorine resin membrane 1, including the preferred range and form, described above in the description of the first embodiment.

### Third Embodiment

The fluorine resin membrane 1 of the present invention can have both high air permeation performance and waterproof performance. In this aspect, a fluorine resin membrane 1 of a third embodiment is a fluorine resin membrane having a network structure of a fluorine resin, having a Gurley air permeability per 1 μm thickness of 5 seconds/100 mL/μm or less, and having a limit water entry pressure of 1.6 MPa or more. The fluorine resin membrane 1 of the third embodiment can have the number A and/or the number B, including the preferred range, described above in the description of the first embodiment. In addition, the fluorine resin membrane 1 of the third embodiment can have the characteristics and/or the membrane configuration of the fluorine resin membrane 1, including the preferred range and form, described above in the description of the first embodiment.

### Fourth Embodiment

The fluorine resin membrane 1 of the present invention can have both high air permeation performance and waterproof performance. In this aspect, a fluorine resin membrane 1 of a fourth embodiment is a fluorine resin membrane having a network structure of a fluorine resin, having a Gurley air permeability per 1 μm thickness of 5 seconds/100 mL/μm or less, and having retention waterproofness that can withstand a water pressure retention test in which the fluorine resin membrane is exposed to a water pressure of 1.0 MPa for 30 minutes when a circular water pressure application surface having a diameter of 1 mm is set. The retention waterproofness of the fluorine resin membrane 1 of the fourth embodiment may be retention waterproofness that can withstand a water pressure retention test in which the fluorine resin membrane 1 is exposed to a water pressure of 1.25 MPa for 30 minutes when a circular water pressure application surface having a diameter of 1 mm is set. The retention waterproofness of the fluorine resin membrane 1 of the fourth embodiment may be retention waterproofness that can withstand a water pressure retention test in which the fluorine resin membrane 1 is exposed to a water pressure of 1.5 MPa for 30 minutes when a circular water pressure application surface having a diameter of 0.2 mm is set.

The fluorine resin membrane 1 of the fourth embodiment can have the number A and/or the number B, including the preferred range, described above in the description of the first embodiment. In addition, the fluorine resin membrane 1 of the fourth embodiment can have the characteristics and/or the membrane configuration of the fluorine resin membrane 1, including the preferred range and form, described above in the description of the first embodiment.

### (Production Method)

A production method for the fluorine resin membrane 1 will be described with the case where the fluorine resin membrane 1 is a PTFE membrane, as an example.

A dispersion liquid of PTFE powder (PTFE dispersion) is applied to a substrate to form a coating. The substrate can be formed from a heat-resistant material such as a heat-resistant resin, a metal, and ceramic. Examples of the heat-resistant resin include polyimide and polyether ether ketone. The coating can be formed by a method of dipping the substrate in the dispersion liquid and then pulling up the substrate, a method of spraying the dispersion liquid onto the substrate, a method of brushing the dispersion liquid onto the substrate, or the like. In order to enhance the wettability to the surface of the substrate, the dispersion liquid may contain a surfactant such as a silicone-based surfactant and a fluorine-based surfactant.

Next, the coating is heated to remove a dispersion medium and to bind PTFE particles to each other. By the heating, a PTFE sheet is formed on the substrate. The heating may be two-step heating in which the coating is heated first at 90 to 150° C. and then at 350 to 400° C. By the heating in the first step, the dispersion medium can be removed, and by the heating in the second step, PTFE can be sintered. The sintering of PTFE means heating PTFE at a temperature equal to or higher than the melting point thereof. The heating may be single-step heating in which the coating is heated at a temperature equal to or higher than the melting point of PTFE from the start. In addition, the thickness of the PTFE sheet may be adjusted by repeating the process of applying the dispersion liquid to the substrate to form a coating and the process of heating the coating. The thickness of the formed PTFE sheet is, for example, 20 to 100 μm, and may be 25 to 80 μm or 30 to 70 μm.

Next, a process of stretching the PTFE sheet peeled off from the substrate in the MD direction (longitudinal direction) and a process of stretching the PTFE sheet in the TD direction (width direction) are performed in this order. It is preferable to perform the stretching in the MD direction (longitudinal stretching), which is the first step, so as not to prevent the PTFE sheet from contracting in the width direction during stretching. For the stretching in the MD direction, for example, a roll-type longitudinal stretching machine can be used. For the stretching in the MD direction, the stretching ratio and the stretching temperature are, for example, 1.5 to 6.0 times and 150 to 380° C., respectively. For the stretching in the TD direction (transverse stretching) which is the second step, for example, a tenter stretching machine can be used. For the stretching in the TD direction, the stretching ratio and the stretching temperature are, for example, 2.0 to 6.0 times and 200 to 380° C., respectively. Calendering of the PTFE sheet peeled off from the substrate is normally not performed. Thus, the fluorine resin membrane 1 can be produced.

### [Fluorine Resin Membrane Member]

An example of a fluorine resin membrane member of the present invention is shown in FIG. 6. A fluorine resin membrane member 21 (21A) in FIG. 6 includes the fluorine resin membrane 1 and a support layer 22 disposed on the fluorine resin membrane 1. The support layer 22 has the same shape as the fluorine resin membrane 1 when viewed in the perpendicular direction. However, the shape of the support layer 22 is not limited to the above examples. The support layer 22 may have the shape of a peripheral portion of the fluorine resin membrane 1, for example, a ring shape or a frame shape.

Examples of the support layer 22 include a woven fabric, a nonwoven fabric, a mesh, a net, a sponge, a foam, and a porous material body formed from a metal, a resin, or a composite material thereof. Examples of the resin include polyolefins, polyesters, polyamides, polyimides, aramids, fluorine resins, and ultra-high-molecular-weight polyethylenes. The support layer 22 may be joined to the fluorine resin membrane 1 by heat lamination, heat welding, ultrasonic welding, or the like.

The support layer 22 normally has air permeability in a thickness direction thereof. The air permeability of the support layer is normally higher than that of the fluorine resin membrane 1.

The fluorine resin membrane member 21A, the fluorine resin membrane 1, and the support layer 22 each have, for example, a shape of a circle, an ellipse, a polygon such as a square and a rectangle, or a stripe, when viewed in the perpendicular direction. However, the shapes thereof are not limited to the above examples.

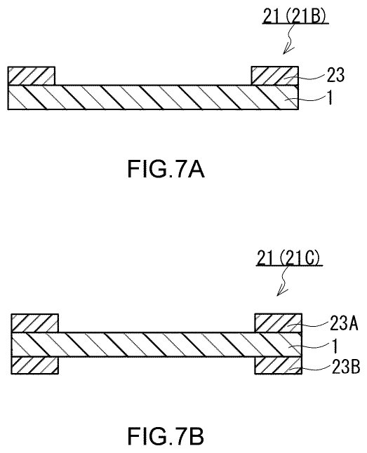

Another example of the fluorine resin membrane member of the present invention is shown in FIG. 7A. A fluorine resin membrane member 21 (21B) in FIG. 7A includes the fluorine resin membrane 1 and an adhesive layer 23 disposed on the fluorine resin membrane 1. The adhesive layer 23 has the shape of the peripheral portion of the fluorine resin membrane 1 when viewed in the perpendicular direction. However, the shape of the adhesive layer 23 is not limited to the above example. In the case where the adhesive layer 23 does not have air permeability in a thickness direction thereof, a region on the inner side of the adhesive layer 23 (region where the adhesive layer 23 is not provided) is a main air-permeable region in the fluorine resin membrane member 21.

The adhesive layer 23 is composed of, for example, a double-coated adhesive tape. The double-coated adhesive tape may be an adhesive tape having a substrate or may be a substrate-less adhesive tape. Examples of the material that can form the substrate are the same as the examples of the material that can form the support layer 22. For an adhesive layer of the double-coated adhesive tape, a known adhesive such as acrylic, silicone, and epoxy adhesives can be used. The adhesive may be thermosetting.

Another example of the fluorine resin membrane member of the present invention is shown in FIG. 7B. A fluorine resin membrane member 21 (21C) in FIG. 7B includes the fluorine resin membrane 1 and a pair of adhesive layers 23A and 23B disposed on the fluorine resin membrane 1 so as to interpose the fluorine resin membrane 1 therebetween.

In the fluorine resin membrane member 21, the fluorine resin membrane 1 may be in direct contact with the support layer 21 and the adhesive layer 23. Another layer may be disposed therebetween.

The fluorine resin membrane member 21 can be distributed commercially in a shape in which the fluorine resin membrane member 21 is to be actually used, and also as a roll of a strip-shaped member. In the case of distributing commercially the fluorine resin membrane member 21 in the shape in which the fluorine resin membrane member 21 is to be actually used, a sheet including a base film and one or two pieces of the fluorine resin membrane member 21 in that shape placed thereon may be distributed commercially. The adhesive layer 23 may be used for joining to the base film. The surface of the base film on which the fluorine resin membrane member(s) 21 is placed may have tackiness. The tackiness of the surface on which the fluorine resin membrane member(s) 21 is placed may be weak tackiness or slight tackiness. The fluorine resin membrane member 21 as a roll can be used, for example, after being punched out into a predetermined shape.

One surface of the fluorine resin membrane 1 included in the fluorine resin membrane member 21 may be subjected to a heat treatment. One example of the heat treatment is hot-pressing for disposing the support layer 22 and/or the adhesive layer 23 on the fluorine resin membrane 1. At the surface of the fluorine resin membrane 1 on which the heat treatment has been performed, for example, at a contact surface of a hot-pressing head used in the hot-pressing, the network structure 11 may be deformed. In other words, in the fluorine resin membrane 1 included in the fluorine resin membrane member 21, a surface opposite to the surface subjected to the heat treatment may have a region A.

### [Electronic Device]

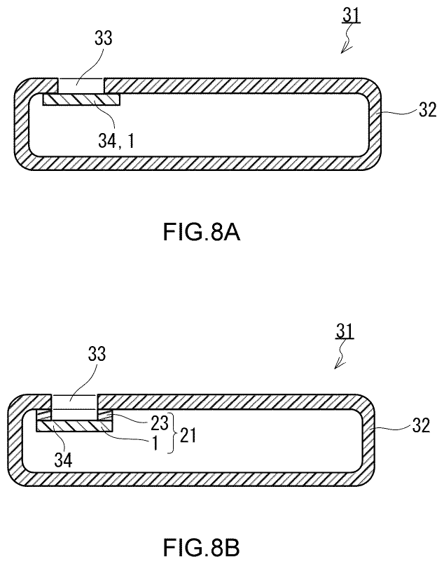

An example of an electronic device of the present invention is shown in FIG. 8A. An electronic device 31 in FIG. 8A has a housing 32 having an opening 33 and a waterproof membrane 34 attached to the housing 32 so as to cover the opening 33. The waterproof membrane 34 is composed of the fluorine resin membrane 1. In the example in FIG. 8A, the waterproof membrane 34 is attached to the inside of the housing 32. However, the position at which the waterproof membrane 34 is attached is not limited to the above example. The waterproof membrane 34 can be attached to the housing 32 using various known methods, such as heat welding, ultrasonic welding, and laser welding. The waterproof membrane 34 may be attached to the housing 32 using an adhesive layer, and the adhesive layer may be the adhesive layer 23 that can be included in the fluorine resin membrane member 21 (see FIG. 8B). In the case where the waterproof membrane 34 is attached using the adhesive layer 23, it may be considered that the fluorine resin membrane member 21 is attached.

The waterproof membrane 34 may include a member and/or a layer other than the fluorine resin membrane 1.

The opening 33 is typically an air vent or internal pressure adjustment opening of the electronic device 31. The opening 33 may be a sound permeation opening through which sound can pass through. However, the opening 33 is not limited to the above examples.

Examples of the electronic device 31 include: portable electronic devices (including wearable devices) such as smartphones, smartwatches, earphones, smart speakers, smart glasses, VR headsets, drones, and action cameras; sensors such as pressure sensors, air pressure sensors, gas sensors, CO₂ sensors, and acoustic sensors; and lamps such as LEDs and lamps including LEDs. However, the electronic device 31 is not limited to the above examples.

### Examples

Hereinafter, the present invention will be described in more detail by way of examples. The present invention is not limited to the examples given below.

First, methods for evaluating the characteristics of fluorine resin membranes (Samples 1 to 12) will be described.

### [Thickness]

The thickness was obtained by measuring the thickness of a fluorine resin membrane punched out in a circle having a diameter of 47 mm, using a micrometer.

### [Mass Per Unit Area]

The mass per unit area was obtained by measuring the mass of a fluorine resin membrane punched out in a circle having a diameter of 47 mm and converting the measured mass into a mass per 1 m² of a principal surface.

### [Gurley Air Permeability]

The Gurley air permeability was evaluated in accordance with Method B of air permeability measurement (Gurley method) prescribed in JIS L 1096:2010.

### [Limit Water Entry Pressure]

The limit water entry pressure was evaluated using the method described above, in accordance with the standards of Method B (high hydraulic pressure method) of water penetration test prescribed in JIS L 1092. The shape of the water passing port in a double-coated adhesive tape for fixing a fluorine resin membrane to the measuring jig was a circle having a diameter of 1.6 mm when viewed in a direction perpendicular to a principal surface of the double-coated adhesive tape.

### [Retention Waterproofness]

The retention waterproofness was evaluated using the water pressure retention test described above. The case where a fluorine resin membrane did not burst or leak water during the water pressure retention test was rated as good (A), and the case where a fluorine resin membrane burst or leaked water during the water pressure retention test was rated as unacceptable (D). The water pressure retention test was conducted under three conditions I to III that are different in the diameter of a water pressure application surface (circle), a water pressure, and a water pressure application time. The conditions are shown in Table 1 below. The retention waterproofness required for the membrane increases in the order of Condition I, Condition II, and Condition III.

TABLE 1

| | Diameter | Water pressure | Water pressure |
|---|---|---|---|
| Condition | (mm) | (MPa) | application time (min) |
| I | 1 | 1.0 | 30 |
| II | 1 | 1.25 | 30 |
| III | 0.2 | 1.5 | 30 |

### [Production of Fluorine Resin Membrane]

### (Sample 1)

1 part by mass of a fluorine-based surfactant (MEGAFAC F-142D, manufactured by DIC Corporation) per 100 parts by mass of PTFE was added to a PTFE dispersion (concentration of PTFE powder: 40% by mass, average particle diameter of PTFE powder: 0.2 μm, containing 6 parts by mass of a nonionic surfactant per 100 parts by mass of PTFE). Next, a long polyimide film (thickness: 125 μm) was immersed in the PTFE dispersion and pulled up to form a coating of the PTFE dispersion on the film. At this time, the thickness of the coating was set to 20 μm using a measuring bar. Next, the coating was heated at 100° C. for 1 minute and then heated at 390° C. for 1 minute to evaporate and remove the water contained in the dispersion and to bind remaining PTFE particles to each other to obtain a PTFE membrane. The above immersion and heating were repeated a plurality of times, and then the PTFE membrane was peeled off from the polyimide film to obtain a PTFE sheet (thickness: 55 μm) as an original sheet.

Next, the obtained PTFE sheet was stretched in the MD direction using a longitudinal stretching machine. The stretching temperature in the MD direction was 280° C., and the stretching ratio in the MD direction was 2 times. During stretching in the MD direction, the PTFE sheet was brought into a state of being free in the width direction. Next, the PTFE sheet was further stretched in the TD direction using a tenter stretching machine to obtain a fluorine resin membrane of Sample 1. The stretching temperature in the TD direction was 300° C., and the stretching ratio in the TD direction was 3.4 times.

### (Samples 2 to 8)

Fluorine resin membranes of Samples 2 to 8 were produced in the same manner as Sample 1, except that the thickness of the original sheet, the stretching ratio in the MD direction, and the stretching temperature and the stretching ratio in the TD direction, which are membrane forming conditions, were changed as shown in Table 2 below.

TABLE 2

| | | Stretching/MD | Stretching/TD direction | |
|---|---|---|---|---|
| | Thickness of | direction | Stretching | Stretching |
| | original sheet | Stretching ratio | temperature | ratio |
| Sample | (μm) | (times) | (° C.) | (times) |
| 1 | 55 | 2 | 300 | 3.4 |
| 2 | 35 | 2.7 | 300 | 4.2 |
| 3 | 35 | 4 | 300 | 2.8 |
| 4 | 55 | 2.7 | 300 | 3.4 |
| 5 | 65 | 2.7 | 300 | 3.6 |
| 6 | 65 | 2.7 | 300 | 3.7 |
| 7 | 65 | 2.7 | 300 | 3.8 |
| 8 | 65 | 2.7 | 300 | 3.9 |

### (Sample 9)

A PTFE sheet (thickness: 25 μm) as an original sheet was produced in the same manner as Sample 1. Next, the produced PTFE sheet was calendered in the MD direction using a roll calendering device. The calendering temperature was 70° C., and the calendering ratio was 1.8 times. Next, the calendered PTFE sheet was further stretched in the TD direction using a tenter stretching machine to obtain a fluorine resin membrane of Sample 9. The stretching temperature in the TD direction was 300° C., and the stretching ratio in the TD direction was 2.2 times.

### (Samples 10 to 12)

Fluorine resin membranes of Samples 10 to 12 were produced in the same manner as Sample 9, except that the thickness of the original sheet, the calendering ratio in the MD direction, and the stretching temperature and the stretching ratio in the TD direction, which are membrane forming conditions, were changed as shown in Table 3 below.

TABLE 3

| | | Calendering/MD | Stretching/TD direction | |
|---|---|---|---|---|
| | Thickness of | direction | Stretching | Stretching |
| | original sheet | Calendering | temperature | ratio |
| Sample | (μm) | ratio (times) | (° C.) | (times) |
| 9 | 20 | 1.8 | 300 | 2.2 |
| 10 | 20 | 2.2 | 300 | 2.2 |
| 11 | 20 | 2.4 | 300 | 2.2 |
| 12 | 25 | 2.0 | 300 | 2.2 |

The surface of the fluorine resin membrane produced in each sample was observed using an FE-SEM, and a rectangular region having a size of 8.3 μm×6.2 μm was evaluated for the following:
(i) the number of first string-shaped bodies extending from one long side to another long side of the region;
(ii) whether a ring structure composed of a first string-shaped body was observed;
(iii) the number of second string-shaped bodies observed inside the largest ring structure existing in the region if the ring structure was observed; and
(iv) whether a third string-shaped body having a length of 1000 nm or more was observed.
   As the FE-SEM, JSM-7500 manufactured by JEOL Ltd. was used, and the acceleration voltage was set to 1 kV.

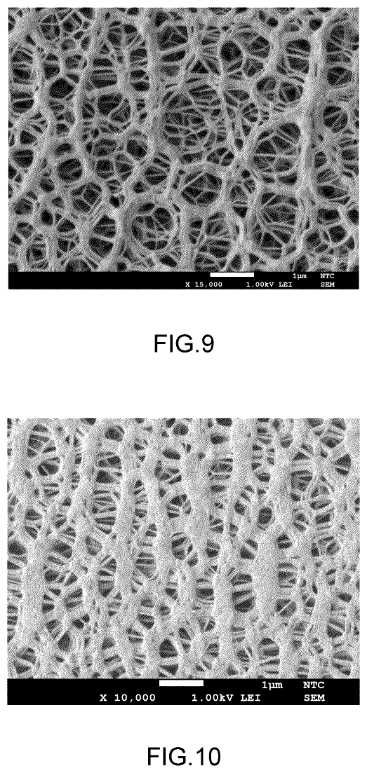

The results of the observation of the region using the FE-SEM and the results of the evaluation of the characteristics for each sample are shown in Table 4 below. In addition, magnified observation images of regions of Samples 2 and 10 observed using the FE-SEM are shown in FIG. 9 and FIG. 10. In Table 4, the “number of first string-shaped bodies” is the number based on the above evaluation (i), and the “number of second string-shaped bodies” is the number based on the above evaluation (iii). The conditions for retention waterproofness are as shown in Table 1.

TABLE 4

| | Observation of region | | |
|---|---|---|---|
| | Number of first | Number of second | Presence/absence |
| | string-shaped | string-shaped | of third string- |
| Sample | bodies | bodies | shaped body |
| 1 | 4 | 18 | Absence |
| 2 | 3 | 22 | Absence |
| 3 | 2 | 14 | Presence |
| 4 | 4 | 25 | Absence |
| 5 | 2 | 13 | Absence |
| 6 | 2 | 13 | Absence |
| 7 | 3 | 15 | Absence |
| 8 | 1 | 10 | Absence |
| 9 | 0 | 4 | Presence |
| 10 | 8 | 3 | Absence |
| 11 | 0 | 4 | Presence |
| 12 | 9 | 3 | Absence |

| | Characteristics | | | | | |
|---|---|---|---|---|---|---|
| | | Gurley air | | | | |
| | | permeability | Limit | | | |
| | | per 1 μm | water | Retention | | |
| | | thickness | entry | waterproofness | | |
| | Thickness | (seconds/100 | pressure | Condition | Condition | Condition |
| Sample | (μm) | mL/μm) | (MPa) | I | II | III |
| 1 | 29 | 3.1 | 2.0 | A | A | D |
| 2 | 7 | 3.3 | 2.0 | A | D | D |
| 3 | 13 | 4.5 | 2.3 | A | D | D |
| 4 | 28 | 2.3 | 2.0 | A | A | D |
| 5 | 34 | 2.4 | 2.1 | A | A | A |
| 6 | 33 | 2.5 | 2.0 | A | A | A |
| 7 | 34 | 2.6 | 2.2 | A | A | A |
| 8 | 33 | 2.7 | 2.2 | A | A | A |
| 9 | 8 | 13.1 | 1.5 | D | D | D |
| 10 | 7 | 6.1 | 1.5 | D | D | D |
| 11 | 7 | 5.7 | 1.5 | D | D | D |
| 12 | 10 | 10 | 2.0 | A | D | D |

* The ring structure in (ii) was observed in all samples.

It was confirmed that Samples 1 to 8 were more suitable for enhancing waterproof performance while minimizing a sacrifice of air permeation performance than Samples 9 to 12.

### INDUSTRIAL APPLICABILITY

The fluorine resin membrane of the present invention can be used in various electronic devices such as portable electronic devices, wearable terminals, and various sensors.

1. A fluorine resin membrane having a network structure of a fluorine resin, wherein
the network structure includes first string-shaped bodies of the fluorine resin,
the first string-shaped bodies have a diameter of 200 nm or more and 750 nm or less when viewed in a direction perpendicular to a principal surface of the fluorine resin membrane, and
when viewed in the direction, the fluorine resin membrane has, on at least one surface thereof, a region A that has a shape of a rectangle having a size of 8.3 m×6.2 μm and in which a number of the first string-shaped bodies extending from one long side to another long side of the rectangle is 1 or more and 5 or less.

2. The fluorine resin membrane according to claim 1, wherein
the network structure further includes second string-shaped bodies of the fluorine resin, and
the second string-shaped bodies have a diameter of less than 200 nm when viewed in a direction perpendicular to the principal surface of the fluorine resin membrane.

3. The fluorine resin membrane according to claim 1, wherein a ring structure composed of the first string-shaped body is observed in the region A.

4. The fluorine resin membrane according to claim 3, wherein
the network structure further includes second string-shaped bodies of the fluorine resin,
the second string-shaped bodies have a diameter of less than 200 nm when viewed in a direction perpendicular to the principal surface of the fluorine resin membrane, and
a number of the second string-shaped bodies observed inside the largest ring structure existing in the region A when viewed in the direction is 6 or more.

5. The fluorine resin membrane according to claim 4, wherein the number of the second string-shaped bodies is 17 or less.

6. The fluorine resin membrane according to claim 1, wherein a proportion of an area of the string-shaped bodies of the fluorine resin in the region A is 60% or less.

7. The fluorine resin membrane according to claim 1, wherein a Gurley air permeability per 1 m thickness of the fluorine resin membrane is 5 seconds/100 mL/μm or less.

8. The fluorine resin membrane according to claim 1, wherein a limit water entry pressure of the fluorine resin membrane is 1.6 MPa or more.

9. The fluorine resin membrane according to claim 1, wherein the fluorine resin membrane has retention waterproofness that can withstand a water pressure retention test in which the fluorine resin membrane is exposed to a water pressure of 1.0 MPa for 30 minutes when a circular water pressure application surface having a diameter of 1 mm is set.

10. The fluorine resin membrane according to claim 1, wherein the fluorine resin is polytetrafluoroethylene.

11. A fluorine resin membrane having a network structure of a fluorine resin, wherein
the network structure includes first string-shaped bodies and second string-shaped bodies of the fluorine resin,
the first string-shaped bodies and the second string-shaped bodies have a diameter of 200 nm or more and 750 nm or less and a diameter of less than 200 nm, respectively, when viewed in a direction perpendicular to a principal surface of the fluorine resin membrane,
when viewed in the direction, the fluorine resin membrane has, on at least one surface thereof, a region B that has a shape of a rectangle having a size of 8.3 m×6.2 μm and in which a ring structure composed of the first string-shaped body is observed, and
a number of the second string-shaped bodies observed inside the largest ring structure existing in the region B when viewed in the direction is 6 or more.

12. A fluorine resin membrane having a network structure of a fluorine resin, wherein
a Gurley air permeability per 1 m thickness of the fluorine resin membrane is 5 seconds/100 mL/μm or less, and
a limit water entry pressure of the fluorine resin membrane is 1.6 MPa or more.

13. A fluorine resin membrane having a network structure of a fluorine resin, wherein
a Gurley air permeability per 1 m thickness of the fluorine resin membrane is 5 seconds/100 mL/μm or less, and
the fluorine resin membrane has retention waterproofness that can withstand a water pressure retention test in which the fluorine resin membrane is exposed to a water pressure of 1.0 MPa for 30 minutes when a circular water pressure application surface having a diameter of 1 mm is set.

14. A fluorine resin membrane member comprising:
the fluorine resin membrane according to claim 1; and
a support layer and/or an adhesive layer.

15. An electronic device comprising:
a housing having an opening; and
a waterproof membrane attached to the housing so as to cover the opening, wherein
the waterproof membrane includes the fluorine resin membrane according to claim 1.
